(19) United States
(12) Patent Application Publication
(10) Pub. No.: US 2026/0040745 A1
(43) Pub. Date: Feb. 5, 2026

(54) LIGHT-EMITTING MODULE

(71) Applicant: NICHIA CORPORATION, Tokushima (JP)

(72) Inventors: Teppei KUNIMUNE, Tokushima-shi (JP); Takuya Sawanobori, Anan-shi (JP)

(21) Appl. No.: 19/284,862

(22) Filed: Jul. 30, 2025

(30) Foreign Application Priority Data
Aug. 1, 2024 (JP) 2024-125905

(51) Int. Cl. H10H 29/851

(52) U.S. Cl. CPC H10H 29/8512

(57) ABSTRACT

A light-emitting module includes: a light-emitting device including a first light-emitting element configured to output first light having a peak wavelength in a range from 430 nm to 480 nm; and a second light-emitting element configured to output second light having a peak wavelength in a range from 500 nm to 600 nm; and a wavelength conversion member configured to absorb light having a wavelength included in at least one of the first light and the second light and output third light having a peak wavelength in a range from 600 nm to 780 nm. The first light-emitting element and the second light-emitting element are disposed in the light-emitting device, and the wavelength conversion member is disposed separately from the light-emitting device.

### CROSS-REFERENCE TO RELATED APPLICATION

This application claims priority to Japanese Patent Application No. 2024-125905, filed on Aug. 1, 2024, the disclosure of which is hereby incorporated by reference in its entirety.

### TECHNICAL FIELD

The present disclosure relates to a light-emitting module.

### BACKGROUND

Techniques for increasing the light use efficiency of a light-emitting module with use of a phosphor have been developed. See, for example, Japanese Patent Publication No. 2016-058586.

### SUMMARY

On the other hand, when a phosphor that absorbs light having a specific wavelength is used, there is an disadvantage that the reliability is lowered. Embodiments according to the present disclosure are to provide a highly reliable light-emitting module using a phosphor.

A light-emitting module according to an aspect of the present disclosure includes: a light-emitting device including a first light-emitting element configured to output first light having a peak wavelength in a range from 430 nm to 480 nm; and a second light-emitting element configured to output second light having a peak wavelength in a range from 500 nm to 600 nm; and a wavelength conversion member configured to absorb light having a wavelength included in at least one of the first light and the second light and output third light having a peak wavelength in a range from 600 nm to 780 nm. The wavelength conversion member is disposed separately from the light-emitting device.

According to the embodiments of the present disclosure, a highly reliable light-emitting module using a phosphor can be obtained.

### BRIEF DESCRIPTION OF DRAWINGS

FIG. 1 is a schematic side view illustrating a light-emitting module according to an embodiment.

FIG. 2 is a schematic perspective view of a light-emitting device according to the embodiment.

FIG. 3 is a schematic view of the light-emitting device according to the embodiment from a plurality of viewpoints.

FIG. 4 is a schematic cross-sectional view taken along line IV-IV in FIG. 3.

FIG. 5 is a schematic cross-sectional view taken along line V-V in FIG. 3.

FIG. 6 is a schematic cross-sectional view taken along line VI-VI in FIG. 3.

FIG. 7 is a table showing production conditions and measurement results of wavelength conversion members according to Examples and Comparative Example.

FIG. 8 is a table showing production conditions and measurement results of wavelength conversion members according to Examples and Comparative Examples.

FIG. 9 is a graph showing a relationship between a wavelength and a total light transmittance measured in each of Examples.

FIG. 10 is a graph showing a relationship between a wavelength and a total light transmittance measured in each of Comparative Examples.

### DETAILED DESCRIPTION

Hereinafter, light-emitting modules according to embodiments of the present disclosure will be described with reference to the drawings. The embodiments illustrated below are examples of a light-emitting device and a method of manufacturing the light-emitting device to embody the technical idea of the present embodiment, and the present invention is not limited to the embodiments illustrated below. Dimensions, materials, shapes, relative arrangements, and the like of constituent members described in the embodiments are not intended to limit the scope of the present disclosure thereto, unless otherwise specified, and are merely exemplary. The sizes, positional relationship, or the like of members illustrated in each of the drawings may be exaggerated for clarity of description. In the following description, members having the same terms and reference characters represent the same members or members of the same quality, and a detailed description of these members is omitted as appropriate. As a cross-sectional view, an end view illustrating only a cut surface may be illustrated.

In the following description, terms indicating specific directions or positions (for example, “upper”, “above”, “lower”, “below” and other terms related to those terms) may be used. However, these terms are used merely to make it easy to understand relative directions or positions in the referenced drawing. As long as the relative direction or position is the same as that described in the referenced drawing using terms such as “upper” “above”, “lower” and “below”, in drawings other than the drawings of the present disclosure, actual products, and the like, components need not be arranged in the same manner as that in the referenced drawing. For example, on the assumption that when two members are present, the positional relationship expressed as “upper”, “above”, “lower”, or “below” in the present specification may encompass a case in which the two members are in contact with each other and a case in which the two members are not in contact with each other and one of the two members is located above (or below) the other member. The term “on” in the present disclosure encompasses both a configuration in which a member is disposed directly on and in contact with another member and a configuration in which a member is disposed on another member with a space or an intervening member interposed therebetween. Further, in the present specification, unless otherwise specified, a case in which a member covers an object to be covered encompasses a case in which the member is in contact with the object to be covered and directly covers the object to be covered, and a case in which the member is not in contact with the object to be covered and indirectly covers the object to be covered.

### 1. Embodiment

### 1.1. Light-Emitting Module 300

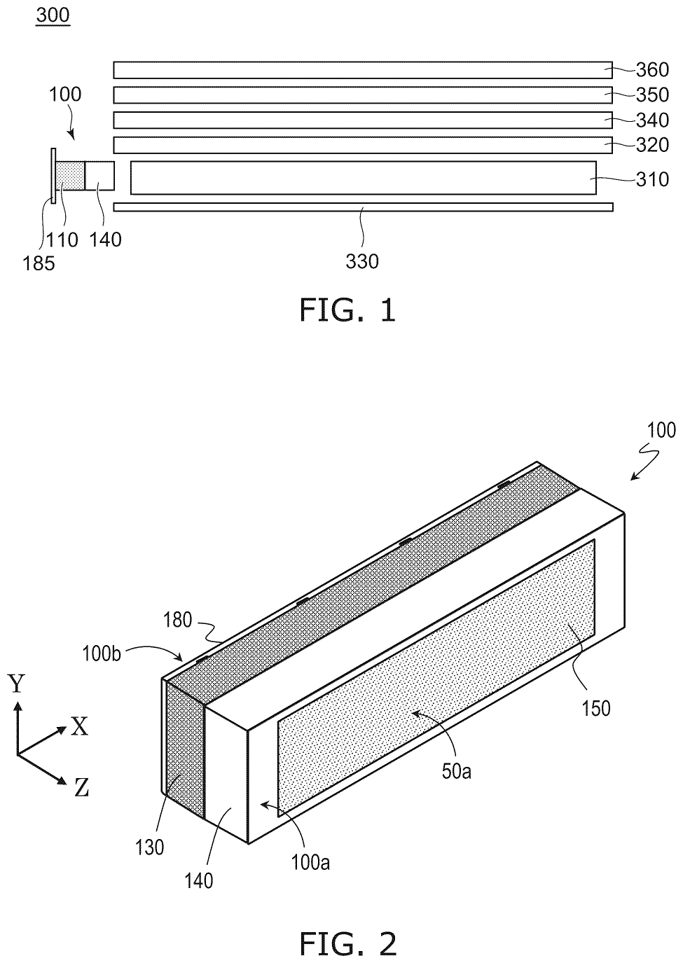

FIG. 1 is a schematic side view illustrating a light-emitting module 300 including a light-emitting device 100 according to an embodiment. As illustrated in FIG. 1, the light-emitting module 300 includes a light-emitting device 100, an optical plate 310 disposed adjacent to the light-emitting device 100, and a wavelength conversion member 320 disposed on the light emission side of the optical plate 310. The light-emitting module 300 includes a plurality of the light-emitting devices 100 that are linearly disposed on a substrate 185, and the plurality of the light-emitting devices 100 can be disposed along the surface of the optical plate 310 on the light incident side. The light-emitting module 300 is, for example, an LED display.

In addition to the light-emitting device 100, the optical plate 310, and the wavelength conversion member 320, the light-emitting module 300 may include one or more of a reflecting plate 330, a prism sheet 340, a polarizing film 350, and a liquid crystal panel 360 as illustrated in FIG. 1, depending on the purpose.

The optical plate 310 is, for example, a light guide member for guiding the primary light emitted from the light-emitting device 100, and is a so-called light guide plate. The light guide plate has, for example, a substantially flat plate shape formed such that at least one surface is a light incident surface and one surface substantially orthogonal to the light incident surface is a light exit surface. The light guide plate mainly includes a resin containing acryl, polycarbonate, or the like as a base material. Resin particles having a refractive index different from that of the resin of the base material may be added to the light guide plate as necessary. Each surface of the light guide plate may have a grain pattern or a notch regularly or irregularly.

The wavelength conversion member 320 may be, for example, a phosphor that contains quantum dots (QDs), absorbs a portion of the light emitted by the light-emitting device 100, and emits light having a wavelength different from that of the absorbed light. The wavelength conversion member 320 is disposed apart from the light-emitting device 100 and disposed in a planar shape along the light-emitting direction of the light-emitting device 100. The quantum dots contained in the wavelength conversion member 320 are each typically a semiconducting nanocrystal having a diameter from 3 nm to 12 nm. The physical diameter of a quantum dot is smaller than the bulk excitation Bohr radius, making quantum confinement effects dominate. As a result, the electronic state, or band gap, of the quantum dot depends on the composition and physical diameter of the quantum dot. That is, in the wavelength conversion member 320, the colors of absorption and emission are related to the diameter of the quantum dot.

The optical quality of quantum dots is directly related to the uniformity of the compositions and physical diameters of the quantum dots. More monodisperse quantum dots result in a smaller full width at half maximum. When quantum dots have a diameter greater than the Bohr radius, the quantum confinement effect may be disrupted and non-radiative pathways for exciton recombination may become dominant, in which case the quantum dot may no longer be luminescent. As an example, quantum dots are a specific subgroup of nanocrystals, defined in particular by their diameters and diameter distribution. The properties of quantum dots are directly related to these parameters, distinguishing them from nanocrystals. Quantum dots are preferable because many of them absorb light having a wavelength shorter than the emission wavelength of the quantum dots and a green LED having a high efficiency and a short wavelength can be used as described later. Among quantum dots, red InP is more preferable because it absorbs green short-wavelength light well.

The wavelength conversion member 320 is, for example, a planar member containing quantum dots, but may be a rod-shaped member containing quantum dots. In the case in which the wavelength conversion member 320 is a planar member, the wavelength conversion member 320 has a length and a width that exceed the thickness. The wavelength conversion member 320 may have a length and a width that are 10 times or more the thickness.

The wavelength conversion member 320 preferably absorbs first light having a peak wavelength included in a range from 430 nm to 480 nm (hereinafter also referred to as blue light) and second light having a peak wavelength included in a range from 500 nm to 600 nm (hereinafter also referred to as green light) emitted from the light-emitting device 100, and emits third light having a peak wavelength included in a range from 600 nm to 780 nm (hereinafter also referred to as red light). In general, the efficiency of an LED having a green wavelength can be higher when the wavelength is shorter. However, if the wavelength is too short, the color reproduction range is narrowed. In a case in which the wavelength conversion member 320 absorbs the second light, because the absorption is basically strong at a short wavelength, the wavelength of the second light becomes long, and a green LED having a short wavelength with high efficiency can be used, and the luminance can be increased. When the second light transmittance, which is the transmittance of the second light in the wavelength conversion member 320, is denoted by T2 and the third light transmittance, which is the transmittance of the third light, is denoted by T3, T2/T3 decreases when the second light is absorbed. Preferably, T2/T3≤0.96. It is preferable that the second light transmittance T2 decreases as the wavelengths of the second light become shorter. A green LED having a high efficiency and a short wavelength can be used, and the luminance can be increased.

The reflecting plate 330 is disposed on a side opposite to an exit direction of light from the optical plate 310. The prism sheet 340 is disposed in an exit direction of light from the optical plate 310. By providing the reflecting plate 330 and the prism sheet 340, it is possible to obtain a backlight which is good in the front luminance, the balance of the viewing angle, and the like. The polarizing film 350 is an optical film for increasing luminance. The liquid crystal panel 360 is a panel that performs video control of a display.

### 1.2. Light-Emitting Device 100

Hereinafter, the light-emitting device 100 will be described in detail.

FIG. 2 is a schematic perspective view of the light-emitting device 100 according to the embodiment.

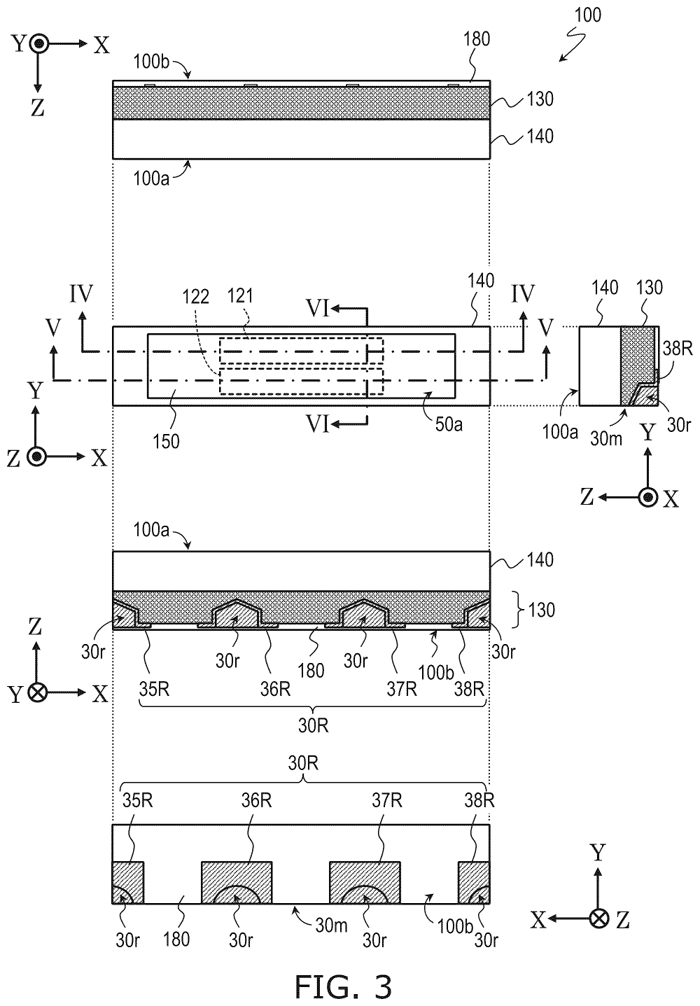

FIG. 3 is a schematic view of the light-emitting device 100 according to the embodiment from a plurality of viewpoints.

The light-emitting device 100 includes a substrate 130, and a first light-emitting element 121 and a second light-emitting element 122 disposed on the substrate 130. The first light-emitting element 121 and the second light-emitting element 122 are, for example, light-emitting diode (LED) chips. The first light-emitting element 121 has a light emission peak wavelength in a first wavelength region. The second light-emitting element 122 has a light emission peak wavelength in a second wavelength region on a longer wavelength side than the first wavelength region. The emission peak wavelength of the first light-emitting element 121 is in a range from 430 nm to 480 nm, and the first light-emitting element 121 is a blue LED chip that mainly emits blue light (first light). The emission peak wavelength of the second light-emitting element 122 is in a range from 500 nm to 600 nm, and the second light-emitting element 122 is a green LED chip that mainly emits green light (second light).

As illustrated in FIG. 2, the light-emitting device 100 has a front surface 100a parallel to the XY plane in the coordinate system illustrated in the drawing. The front surface 100a of the light-emitting device 100 has a rectangular shape that is longer in the X direction than in the Y direction. The light-emitting device 100 can be used as a lateral surface emission type light-emitting device in which light enters a light guide plate from a lateral surface of the light guide plate, as a light source for a backlight.

The light-emitting device 100 includes the substrate 130, a light reflective member 140, and a light-transmissive member 150. As described later, the light-transmissive member 150 may contain a wavelength conversion member such as a phosphor. The light-transmissive member 150 has a light extraction surface 50a parallel to the XY plane. Here, the light extraction surface 50a is a part of the front surface 100a. The light reflective member 140 is located around the light extraction surface 50a.

As illustrated in FIG. 3, the light-emitting device 100 includes a lower surface wiring 30R on the back surface 100b side opposite to the front surface 100a. The lower surface wiring 30R includes a total of four wirings, that is, a fifth wiring 35R, a sixth wiring 36R, a seventh wiring 37R, and an eighth wiring 38R. The fifth wiring 35R, the sixth wiring 36R, the seventh wiring 37R, and the eighth wiring 38R are disposed in a line along the X-direction (X-direction) at intervals from each other. In this example, an insulating layer 180 for preventing a short circuit between two terminals adjacent to each other is disposed on the back surface 100b of the light-emitting device 100.

In an embodiment of the present disclosure, the first light-emitting element 121 and the second light-emitting element 122 are disposed in a line along the Y direction in the light-emitting device 100. In the example illustrated in FIG. 3, the first light-emitting element 121 is located on the +Y direction side (the upper side in a state in which the light-emitting device 100 is mounted on a wiring substrate or the like) with respect to the second light-emitting element 122. However, the arrangement of the first light-emitting element 121 and the second light-emitting element 122 in the light-emitting device 100 is not limited to the example illustrated in FIG. 3.

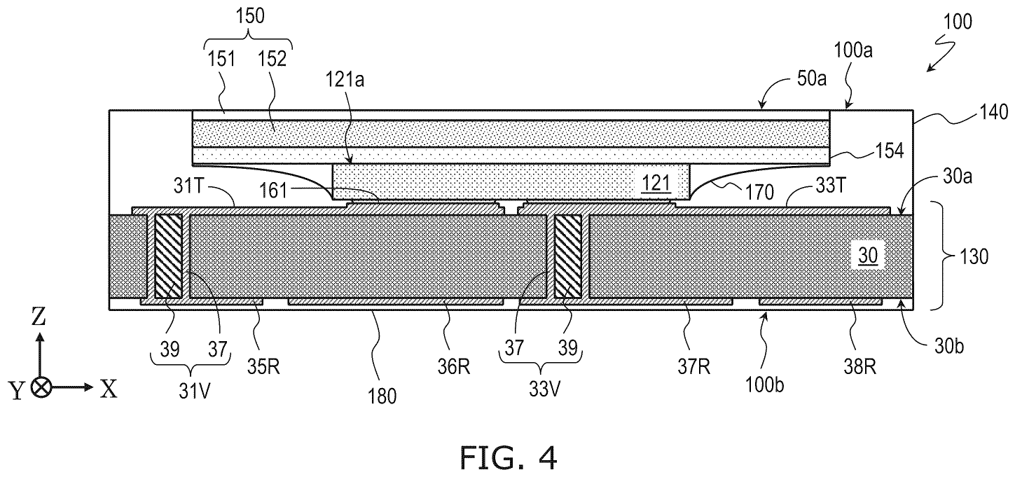

FIG. 4 is a schematic cross-sectional view taken along line IV-IV in FIG. 3.

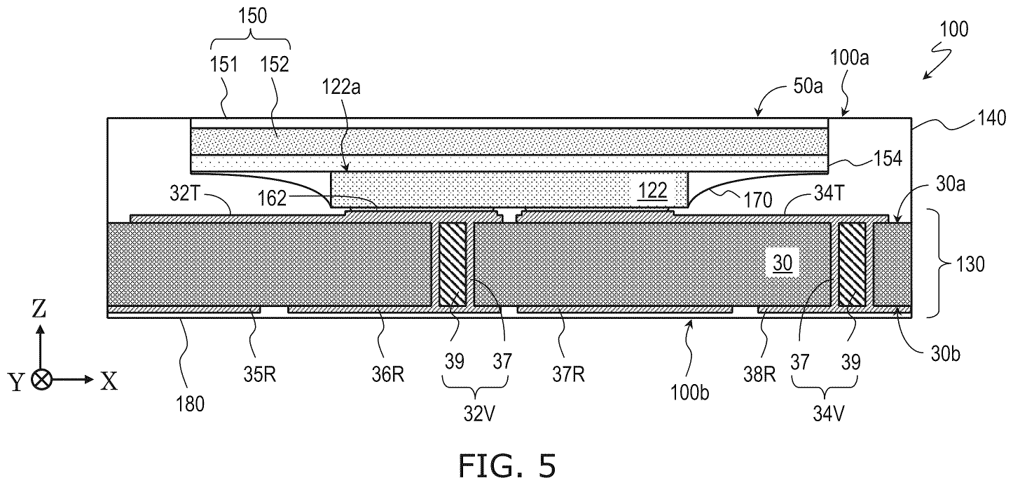

FIG. 5 is a schematic cross-sectional view taken along line V-V in FIG. 3.

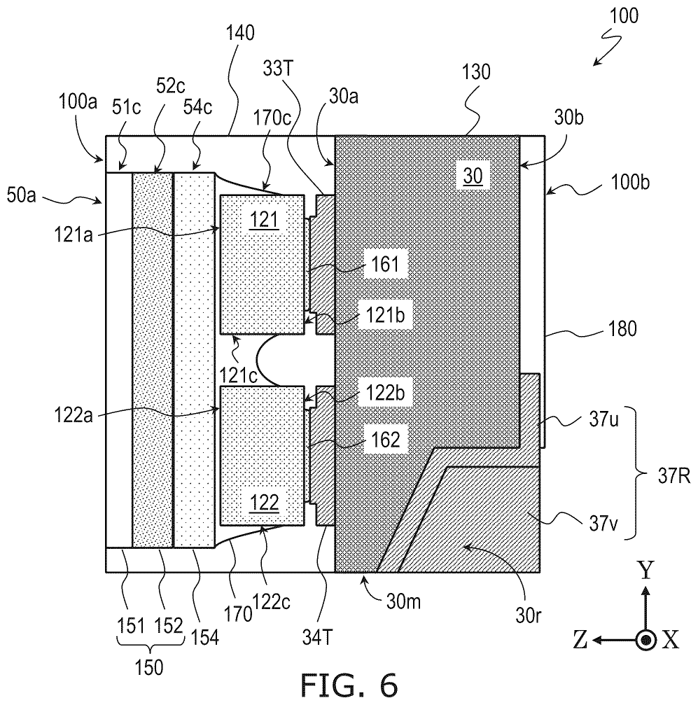

FIG. 6 is a schematic cross-sectional view taken along line VI-VI in FIG. 3.

The substrate 130 has an upper surface having a rectangular shape defined by short sides extending in the Y direction and long sides extending in the X direction. The substrate 130 includes a base member 30 having an insulating property, an upper surface wiring, and the lower surface wiring 30R described above. The base member 30 has an upper surface 30a and a lower surface 30b located on a side opposite to the upper surface 30a. The upper surface wiring is located on the upper surface 30a of the base member 30. The upper surface of the substrate 130 includes the upper surface 30a of the base member 30 and the upper surface of the upper surface wiring. The lower surface wiring 30R is located on the lower surface 30b of the base member 30.

The upper surface wiring includes four wirings of a first wiring 31T to a fourth wiring 34T. As illustrated in FIG. 4, the substrate 130 is provided with the first wiring 31T and the third wiring 33T, each of which is located on the upper surface 30a. Further, as illustrated in FIG. 5, the substrate 130 is provided with a second wiring 32T and a fourth wiring 34T, each of which is located on the upper surface 30a.

The substrate 130 further includes, inside the base member 30, a plurality of conductive portions each of which extends from the upper surface 30a to the lower surface 30b of the base member 30 and connects the upper surface wiring and the lower surface wiring. In the present embodiment, four conductive portions including a first conductive portion 31V, a second conductive portion 32V, a third conductive portion 33V, and a fourth conductive portion 34V are disposed inside the base member 30.

As illustrated in FIG. 4, the first conductive portion 31V connects the first wiring 31T and the fifth wiring 35R, and electrically connects them to each other. The third conductive portion 33V connects the third wiring 33T and the seventh wiring 37R, and electrically connects them to each other. In the present embodiment, of the first conductive portion 31V and the third conductive portion 33V, the third conductive portion 33V is located below the first light-emitting element 121.

As illustrated in FIG. 5, the second conductive portion 32V connects the second wiring 32T and the sixth wiring 36R, and electrically connects them to each other. The fourth conductive portion 34V connects the fourth wiring 34T and the eighth wiring 38R, and electrically connects them to each other. In the present embodiment, of the second conductive portion 32V and the fourth conductive portion 34V, the second conductive portion 32V is located below the second light-emitting element 122.

### 1.2.1. Substrate 130

Hereinafter, components included in the light-emitting device 100 will be described in detail. The substrate 130 is a support member on which the first light-emitting element 121 and the second light-emitting element 122 are mounted. As described above, the first light-emitting element 121 and the second light-emitting element 122 are disposed on the substrate 130 in a line along the Y direction. As will be described later, in the embodiment of the present disclosure, an element having a shape with a relatively large aspect ratio in the X direction with respect to the Y direction can be used as each of the first light-emitting element 121 and the second light-emitting element 122. Correspondingly, the substrate 130 may also have a shape that is relatively long in the X direction as a whole.

The base member 30 of the substrate 130 is an insulating member having a substantially rectangular parallelepiped shape provided with the first wiring 31T, the second wiring 32T, the third wiring 33T, and the fourth wiring 34T disposed on the upper surface 30a thereof. The dimension of the base member 30 in the Y direction is, for example, in a range from 400 μm to 800 μm. The dimension of the base member 30 in the X direction is, for example, in a range from 1800 μm to 5000 μm. The dimension of the base member 30 in the Z direction is, for example, in a range from 200 μm to 1000 μm.

Examples of the material of the base member 30 include resins, ceramics, and glass. As the material of the base member 30, for example, bismaleimide triazine (BT) can be applied. The base member 30 may be formed of a composite material such as a fiber-reinforced resin, and, for example, a glass epoxy substrate may be applied to the base member 30. In addition, epoxy, polyimide, or the like can be used as the base material of the base member 30. As the ceramics, aluminum oxide, aluminum nitride, zirconium oxide, zirconium nitride, titanium oxide, titanium nitride, and a mixture of two or more of these can be applied. Among these ceramics, it is advantageous to use a material having a linear expansion coefficient close to the linear expansion coefficient of the first light-emitting element 121 or the second light-emitting element 122 as the material of the base member 30.

Examples of the material of the fifth wiring 35R, the sixth wiring 36R, the seventh wiring 37R and the eighth wiring 38R on the lower surface 30b side of the base member 30 and the material of the first wiring 31T, the second wiring 32T, the third wiring 33T and the fourth wiring 34T on the upper surface 30a side of the base member 30 include copper, iron, nickel, tungsten, chromium, aluminum, silver, platinum, gold, titanium, palladium, rhodium, and alloys containing one or more of these metals. From the viewpoint of heat dissipation, it is advantageous to apply copper or a copper alloy to the material of these wirings. The upper surface wiring and/or the lower surface wiring may be a single-layer film or a layered film. The outermost surface of the upper surface wiring and/or the lower surface wiring, which is formed of silver, platinum, aluminum, rhodium, gold, or an alloy containing one or more of these metals, is advantageous because good wettability to solder can be obtained.

Each of the first conductive portion 31V to the fourth conductive portion 34V may be a conductive member occupying the entire inside the through hole provided in the base member 30, or may be a combination of a conductive film disposed on the inner lateral surface of the through hole and an insulating filling member. For example, a material the same as or similar to that of the lower surface wiring on the lower surface 30b side of the base member 30 can be applied to the conductive film covering the inner lateral surface of the through hole. The region surrounded by the conductive film may be occupied by an insulating material such as an epoxy resin. In the example illustrated in FIGS. 4 and 5, each of the first conductive portion 31V to the fourth conductive portion 34V includes a conductive film 37 covering the inner lateral surface of the through hole provided in the base member 30, and an insulating portion 39 located in a region surrounded by the conductive film 37.

### 1.2.2. First Light-Emitting Element 121 and Second Light-Emitting Element 122

The first light-emitting element 121 and the second light-emitting element 122 may have substantially the same basic configuration except for the light emission peak wavelength described above. In the following, a description of the configuration of the second light-emitting element 122 that is the same as that of the first light-emitting element 121 may be omitted.

In the embodiment of the present disclosure, the first light-emitting element 121 and the second light-emitting element 122 are mounted on the substrate provided with the first wiring 31T to the fourth wiring 34T by flip-chip connection. As illustrated in FIG. 4, the first light-emitting element 121 is electrically connected to the first wiring 31T and the third wiring 33T on the base member 30. As illustrated in FIG. 5, the second light-emitting element 122 is electrically connected to the second wiring 32T and the fourth wiring 34T on the base member 30.

As illustrated in FIGS. 4 and 6, the first light-emitting element 121 has an element upper surface 121a and an element lower surface 121b opposite to the element upper surface 121a. In addition, the first light-emitting element 121 includes a positive electrode and a negative electrode on the element lower surface 121b. As illustrated in FIGS. 5 and 6, the second light-emitting element 122 has an element upper surface 122a and an element lower surface 122b opposite to the element upper surface 122a. The second light-emitting element 122 includes a positive electrode and a negative electrode on the element lower surface 122b. Examples of the material of the electrodes (the positive electrode and the negative electrode) of the first light-emitting element 121 and the second light-emitting element 122 include gold, silver, tin, platinum, rhodium, titanium, aluminum, tungsten, palladium, nickel, and an alloy containing one or more of these metals.

The first light-emitting element 121 is mounted on the substrate 130 by connecting and fixing the electrodes on the element lower surface 121b side to the first wiring 31T and the third wiring 33T with a bonding member 161 such as solder. The second light-emitting element 122 is mounted on the substrate 130 by connecting and fixing the electrodes on the element lower surface 122b side to the second wiring 32T and the fourth wiring 34T with a bonding member 162 such as solder.

Each of the first light-emitting element 121 and the second light-emitting element 122 has a semiconductor structure. The semiconductor structure includes an n-side semiconductor layer, a p-side semiconductor layer, and an active layer interposed between the n-side semiconductor layer and the p-side semiconductor layer. The active layer may have a single quantum well (SQW) structure, or may have a multi quantum well (MQW) structure including a plurality of well layers. The semiconductor structure includes a plurality of semiconductor layers each formed of a nitride semiconductor. The nitride semiconductor includes, in its category, semiconductors having all compositions in which, in a chemical formula of InₓAl_{y}Ga_{1-x-y}N (0≤x, 0≤y, and x+y≤1), composition ratios x and y are changed within their respective ranges. The semiconductor structures of the first light-emitting element 121 and the second light-emitting element 122 are selected such that the forward voltage Vf of the second light-emitting element 122 is lower than the forward voltage Vf of the first light-emitting element 121.

The semiconductor structures may include a plurality of light-emitting portions each including an n-side semiconductor layer, an active layer, and a p-side semiconductor layer. When the semiconductor structures include the plurality of light-emitting portions, the plurality of light-emitting portions may include well layers having different light emission peak wavelengths or well layers having the same light emission peak wavelength. The expression “having the same light emission peak wavelength” includes a case in which there is a variation of several nanometers. The combination of the light emission peak wavelengths of the plurality of light-emitting portions can be selected as appropriate.

In the embodiment of the present disclosure, an element having a shape that is relatively longer in the X direction than in the Y direction is used as each of the first light-emitting element 121 and the second light-emitting element 122. The length of the element upper surface 121a of the first light-emitting element 121 along the Y direction can be, for example, in a range from 150 μm to 300 μm, and the length thereof along the X direction can be, for example, in a range from 400 μm to 1500 μm. The ratio of the length of the element upper surface 121a of the first light-emitting element 121 along the X direction to the length thereof along the Y direction is, for example, in a range from 1.1 to 10. The same applies to the dimensions of the element upper surface 122a of the second light-emitting element 122. By arranging the first light-emitting element 121 and the second light-emitting element 122, which are relatively long in the X direction, in the Y direction (i.e., in a line in the Y direction), it is possible to achieve high light extraction efficiency while reducing the number of light-emitting elements in the X direction. The reduction in warpage of the substrate 130 is also advantageous for mounting such a long element on the substrate 130.

### 1.2.3. Light-Transmissive Member 150

The light-transmissive member 150 is a plate-shaped member having a function of protecting the first light-emitting element 121 and the second light-emitting element 122. The upper surface of the light-transmissive member 150 constitutes the light extraction surface 50a of the light-emitting device 100. The light-transmissive member 150 is formed of, for example, a silicone resin as a base material, and has a light-transmissive property.

The light-transmissive member 150 has, for example, a transmittance of 60% or more with respect to light having the emission peak wavelength of the first light-emitting element 121. In addition, the light-transmissive member 150 may exhibit a transmittance of 60% or more with respect to light having an emission peak wavelength of the second light-emitting element 122. In terms of effective use of light, the transmittance of the light-transmissive member 150 at the emission peak wavelength of at least one of the first light-emitting element 121 and the second light-emitting element 122 is advantageously 70% or more, more advantageously 80% or more.

In the present embodiment, the light-transmissive member 150 is disposed above the first light-emitting element 121 and above the second light-emitting element 122 so as to collectively cover the element upper surface 121a of the first light-emitting element 121 and the element upper surface 122a of the second light-emitting element 122. With the single light-transmissive member 150 covering both the first light-emitting element 121 and the second light-emitting element 122, light from the first light-emitting element 121 and light from the second light-emitting element 122 can be efficiently mixed inside the light-transmissive member 150.

Examples of the base material of the light-transmissive member 150 include a silicone resin, a modified silicone resin, an epoxy resin, a modified epoxy resin, a urea resin, a phenol resin, a polycarbonate resin, a trimethylpentene resin, a polynorbornene resin, an acrylic resin, a urethane resin, a fluororesin, and a resin containing two or more of these resins. Glass may be selected as the base material of a wavelength conversion layer 152. The base material of the light-transmissive member 150 may contain a wavelength conversion member such as a phosphor.

In the configuration illustrated in FIG. 6, the light-transmissive member 150 includes a protective layer 151 and a wavelength conversion layer 152. The protective layer 151 is located farther from the substrate 130 than the wavelength conversion layer 152 is. In other words, in this example, the wavelength conversion layer 152 is located between the protective layer 151 and the set of the first light-emitting element 121 and the second light-emitting element 122.

The wavelength conversion layer 152 is a plate-shaped member containing a wavelength conversion member, and converts the wavelength of a part of incident light to emit, for example, light having a different wavelength. As the wavelength conversion member contained in the base material of the wavelength conversion layer 152, a known phosphor can be used. As the phosphor, an yttrium-aluminum-garnet-based phosphor (for example, Y3(Al,Ga)5O12:Ce), a lutetium-aluminum-garnet-based phosphor (for example, Lu3(Al,Ga)5O12:Ce), a terbium-aluminum-garnet-based phosphor (for example, Tb3(Al,Ga)5O12:Ce), a CCA-based phosphor (for example, Ca10(PO4)6Cl2:Eu), a SAE-based phosphor (for example, Sr4Al14O25:Eu), a chlorosilicate-based phosphor (for example, Ca8MgSi4O16Cl2:Eu), an oxynitride-based phosphor, a nitride-based phosphor, a fluoride-based phosphor, a phosphor having a perovskite structure (for example, CsPb(F,Cl,Br,I)3), a quantum-dot phosphor (for example, CdSe, InP, AgInS2, or AgInSe2), or the like can be used. Typical examples of the oxynitride-based phosphor include β-sialon-based phosphors (for example, (Si,Al)3(O,N)4:Eu) and α-sialon-based phosphors (for example, Ca(Si,Al)12(O,N)16:Eu). Typical examples of the nitride-based phosphor include SLA-based phosphors (for example, SrLiAl3N4:Eu), CASN-based phosphors (for example, CaAlSiN3:Eu), and SCASN-based phosphors (for example, (Sr,Ca)AlSiN3:Eu). Typical examples of the fluoride-based phosphor include KSF-based phosphors (for example, K2SiF6:Mn), KSAF-based phosphors (for example, K2Si0.99Al0.01F5.99:Mn), and MGF-based phosphors (for example, 3.5MgO·0.5MgF2·GeO2:Mn).

As the phosphor in the wavelength conversion layer 152, in particular, a fluoride-based phosphor such as a KSF-based phosphor (for example, K2SiF6:Mn), a KSAF-based phosphor (for example, K2Si0.99Al0.01F5.99:Mn), or an MGF-based phosphor (for example, 3.5MgO·0.5MgF2·GeO2:Mn), a phosphor having a perovskite structure (for example, CsPb (F,Cl,Br,I)3), a quantum-dot phosphor (for example, CdSe, InP, AgInS2, or AgInSe2), or the like can be used. With such selection of the light-emitting elements and the phosphor, because the wavelength conversion layer 152 absorbs a part of the light from the light-emitting elements and emits light in the red wavelength region, white light can be obtained by mixing the light in the red wavelength region with the blue light and the green light transmitted through the wavelength conversion layer 152. In a case in which a wavelength conversion layer containing a phosphor that emits red light by excitation is disposed above the LED that emits blue light and the LED that emits green light, a configuration in which the LED that emits blue light is selectively covered with the wavelength conversion layer, in other words, a configuration in which the LED that emits green light is not covered with the wavelength conversion layer is also employed. However, from the viewpoint of obtaining white light with reduced color unevenness, the wavelength conversion layer 152 is preferably disposed so as to cover both the LED that emits blue light and the LED that emits green light.

The wavelength conversion layer 152 may contain one of the above-described phosphors alone, may contain two or more of these phosphors in combination, or does not have to contain a phosphor. In the case in which the wavelength conversion layer 152 contains two or more of the phosphors, it is advantageous to adjust the distribution of the wavelength conversion members in the wavelength conversion layer 152 such that a phosphor that emits light having a shorter wavelength among the phosphors is located closer to the light-emitting elements. Alternatively, the wavelength conversion layer may include two layers, and different types of phosphors may be contained in the respective layers. In this case, it is advantageous that a phosphor that emits light on the shorter wavelength side by excitation is contained in a layer on the side closer to the light-emitting elements.

A light diffusion function may be imparted to the wavelength conversion layer 152 by dispersing a material having a refractive index different from that of the base material in the material of the wavelength conversion layer 152. For example, the wavelength conversion layer 152 may contain a light diffusion material described later.

The protective layer 151 is a light-transmissive layer located on the outermost surface of the light-transmissive member 150 on the side opposite to the first light-emitting element 121 and the second light-emitting element 122. The upper surface of the protective layer 151 constitutes the light extraction surface 50a of the light-transmissive member 150, and in the example illustrated in FIG. 6, the upper surface of the protective layer 151 is aligned with the front surface 100a of the light-emitting device 100.

A material the same as or similar to the base material of the wavelength conversion layer 152, such as a silicone resin or an epoxy resin, can be used as the base material of the protective layer 151. From the viewpoint of efficiently introducing light into the protective layer 151, it is advantageous that the material of the protective layer 151 has a higher refractive index than the material of the wavelength conversion layer 152. A light diffusion function may be imparted to the protective layer 151 by dispersing a light diffusion material having a refractive index different from that of the base material in the base material.

### 1.2.4. Light Diffusion Member 154

In the configuration illustrated in FIG. 6, the light-emitting device 100 further includes a light diffusion member 154. The light diffusion member 154 is a plate-shaped member disposed between the element upper surface 121a of the first light-emitting element 121 and the light-transmissive member 150 and between the element upper surface 122a of the second light-emitting element 122 and the light-transmissive member 150.

The light diffusion member 154 contains a light-transmissive base material and a light diffusion material dispersed in the base material. As in the protective layer 151, a material the same as or similar to the base material of the wavelength conversion layer 152 can be used as the base material of the light diffusion member 154. As the light diffusion material, for example, resin particles having a refractive index different from that of the base material, or particles of silicon oxide, aluminum oxide, zirconium oxide, zinc oxide, or the like can be used. As the light diffusion material dispersed in the base material, nanoparticles having a particle diameter defined by D50 in a range from 1 nm to 100 nm may be used. By using nanoparticles as the light diffusion material, light scattering in the light diffusion member 154 can be increased.

### 1.2.5. Light Guide Member 170

In the configuration illustrated in FIGS. 4 to 6, the light-emitting device 100 further includes a light guide member 170. In this example, by disposing the light guide member 170, the light diffusion member 154 is disposed above the element upper surface 121a of the first light-emitting element 121 and the element upper surface 122a of the second light-emitting element 122. The light guide member 170 includes at least a portion located on the element lateral surface 121c of the first light-emitting element 121 and a portion located on the element lateral surface 122c of the second light-emitting element 122.

As the material of the light guide member 170, a resin material containing a transparent resin as a base material can be used. The base material of the light guide member 170 may be, for example, a material the same as or similar to the base material of the light-transmissive member 150. The light guide member 170 may have a light diffusion function by dispersing a light diffusion material having a refractive index different from that of the base material. The refractive index of the light guide member 170 may be set higher than the refractive index of the light-transmissive member 150 and lower than the refractive indices of the first light-emitting element 121 and the second light-emitting element 122. The light guide member 170 may be formed of, for example, a material having a refractive index in a range from 1.52 to 1.60. When such a refractive index relationship is satisfied, the refractive index gradually decreases from the first light-emitting element 121 and the second light-emitting element 122 toward the light-transmissive member 150, so that the efficiency of emission of light from the first light-emitting element 121 and the second light-emitting element 122 to the outside of the light-emitting device 100 can be improved.

The light guide member 170 includes a portion located between the element lateral surface 121c of the first light-emitting element 121 and the light reflective member 140. With the light guide member 170, part of the light emitted from the first light-emitting element 121 through the element lateral surface 121c can enter the light diffusion member 154 (or the light-transmissive member 150) by reflection at the interface between the light guide member 170 and the light reflective member 140. That is, the light incident on the light guide member 170 is reflected toward the light diffusion member 154 at the position of the outer surface 170c of the light guide member 170, and exits toward the outside of the light-emitting device 100 through the light diffusion member 154 and the light-transmissive member 150. The same applies to a portion of the light emitted from the second light-emitting element 122 that exits through the element lateral surface 122c. With the light guide member 170, the light extraction efficiency of the light-emitting device 100 can be improved.

The light guide member 170 is formed by curing a liquid resin, for example. Because the size of the light-emitting device 100 in the Y direction is smaller than the size thereof in the X direction, the light guide member 170 is more likely to be formed to bulge in the short-side direction than in the long-side direction of the light-emitting elements. As a result, in the light guide member 170 disposed on the element lateral surfaces 121c and 122c respectively parallel to the X direction of the first light-emitting element 121 and the X direction of the second light-emitting element 122, the thickness in the Y direction of the lower portion located on the element lower surfaces 121b and 122b side can be made larger than the thickness in the Y direction of the upper portion located on the element upper surfaces 121a and 122a side. With such a structure, light emitted from the element lateral surfaces 121c and 122c of the first light-emitting element 121 and the second light-emitting element 122 can be easily reflected upward at the interface between the lower portion of the light guide member 170 and the light reflective member 140, so that the efficiency of light extraction from the light extraction surface 50a of the light-emitting device 100 can be improved.

### 1.2.6. Light Reflective Member 140

The light reflective member 140 surrounds the set of the first light-emitting element 121 and the second light-emitting element 122 and the light-transmissive member 150 on the substrate 130. In the present specification, the term “light reflective” means that the reflectance to the emission peak wavelength of the light-emitting element (the first light-emitting element 121 or the second light-emitting element 122) is 60% or more. The reflectance of the light reflective member 140 to the emission peak wavelength of the light-emitting element is more advantageously 70% or more, further advantageously 80% or more.

Examples of the material of the light reflective member 140 include a resin material in which a light diffusion material is dispersed. The base material of the light reflective member 140 may be, for example, a silicone resin, a modified silicone resin, an epoxy resin, a urea resin, a polycarbonate resin, a phenol resin, an acrylic resin, a urethane resin, a fluororesin, a modified resin of any of these resins, or a resin containing two or more of these resins. As the light diffusion material, particles of an inorganic material or an organic material having a refractive index higher than that of the base material can be used. Examples of the light diffusion material include particles of titanium oxide, magnesium oxide, zirconium dioxide, potassium titanate, aluminum oxide, aluminum nitride, boron nitride, mullite, niobium oxide, barium sulfate, silicon oxide, various rare earth oxides (for example, yttrium oxide and gadolinium oxide), and the like. The light reflective member 140 may have a white color.

As illustrated in FIGS. 4 to 6, the light reflective member 140 covers the structure on the upper surface 30a of the base member 30 except for the light extraction surface 50a of the light-transmissive member 150. The light reflective member 140 is in contact with the lateral surface 51c of the protective layer 151, the lateral surface 52c of the wavelength conversion layer 152, and the lateral surface 54c of the light diffusion member 154. At least a portion of the light reflective member 140 faces the element lateral surface 121c of the first light-emitting element 121 and the element lateral surface 122c of the second light-emitting element 122. In other words, at least a portion of the light reflective member 140 can be in contact with the element lateral surface 121c of the first light-emitting element 121 and the element lateral surface 122c of the second light-emitting element 122.

A portion of the light reflective member 140 can also be located between the first light-emitting element 121 and the substrate 130 and between the second light-emitting element 122 and the substrate 130. Disposing the light reflective member 140 on the element lower surface 121b side of the first light-emitting element 121 and the element lower surface 122b side of the second light-emitting element 122 can reduce light emission from the element lower surface sides of the light-emitting elements, so that the effect of improving the light use efficiency can be obtained.

### 1.3. Examples

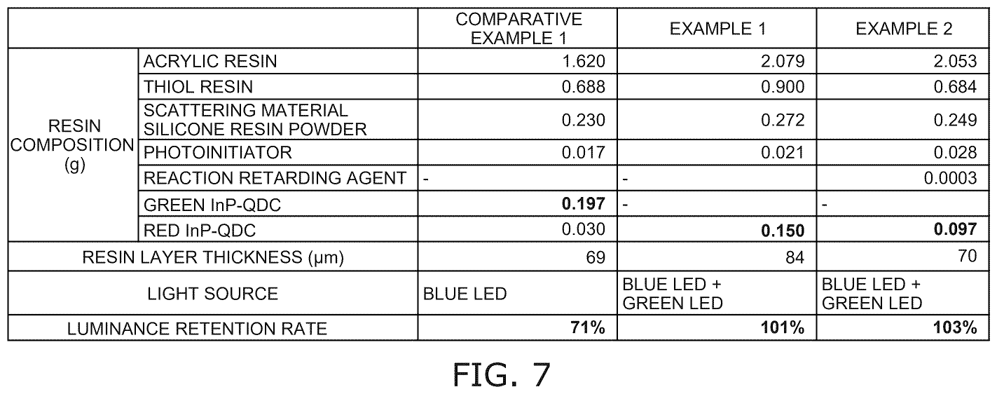

Examples will be described with reference to FIGS. 7 to 10.

FIG. 7 is a table showing production conditions and measurement results of wavelength conversion members according to Examples and Comparative Example.

The wavelength conversion members 320 in Examples 1 and 2 and a wavelength conversion member C in Comparative Example 1 were produced under the resin blending conditions shown in FIG. 7. To be specific, in Example 1, a resin composition was obtained by mixing 2.079 g of an acrylic resin, 0.900 g of a thiol resin, 0.272 g of a scattering material silicone resin powder, 0.021 g of a photoinitiator, and 0.150 g of an InP quantum dot-concentrated liquid (red InP-QDC) that absorbs at least one of blue light and green light and emits red light.

In Example 2, 2.053 g of an acrylic resin, 0.684 g of a thiol resin, 0.249 g of a scattering material silicone resin powder, 0.028 g of a photoinitiator, 0.0003 g of a reaction retarding agent, and 0.097 g of red InP-QDC were mixed to obtain a resin composition.

In Comparative Example 1, 1.620 g of an acrylic resin, 0.688 g of a thiol resin, 0.230 g of a scattering material silicone resin powder, 0.017 g of a photoinitiator, 0.197 g of an InP quantum dot-concentrated liquid (green InP-QDC) that absorbs at least one of blue light and green light and emits green light, and 0.030 g of red InP-QDC were mixed to obtain a resin composition.

Each of these resin compositions was formed into a sheet shape, and barrier films were disposed so as to sandwich the top and bottom of each of the sheets of the resin compositions. Further, each of the sheets of the resin compositions was irradiated with UV light at room temperature to UV-cure the resin of each of the sheets, thereby obtaining the wavelength conversion members 320 of Examples and the wavelength conversion member C of Comparative Example. The thickness of the resin layer (sheet) not including the barrier film was 84 μm for Example 1, 70 μm for Example 2, and 69 μm for Comparative Example 1.

For each of Examples 1 and 2 and Comparative Example 1, the luminance retention rate after 2000 hours was measured. As for the exciting power conditions, the power of the light sources was adjusted so as to obtain 50000 nit with white light power. The light sources in Example 1 and Example 2 were the first light-emitting element 121 and the second light-emitting element 122. The light source in Comparative Example 1 was one light-emitting element that outputs blue light. The measured luminance retention rates were 101 percent for Example 1, 103 percent for Example 2, and 71 percent for Comparative Example 1. As described above, the reliability of the light-emitting module 300 was improved by using the wavelength conversion member 320 in Example 1 and Example 2. When Examples 1 and 2 are compared, the reliability was improved regardless of the concentration of the quantum dots.

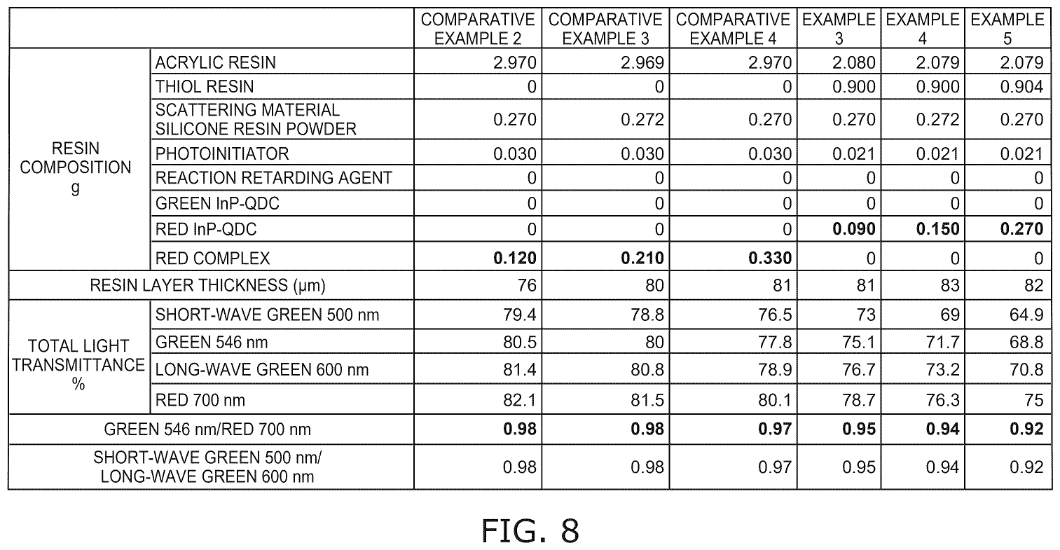

FIG. 8 is a table showing production conditions and measurement results of wavelength conversion members according to Examples and Comparative Examples.

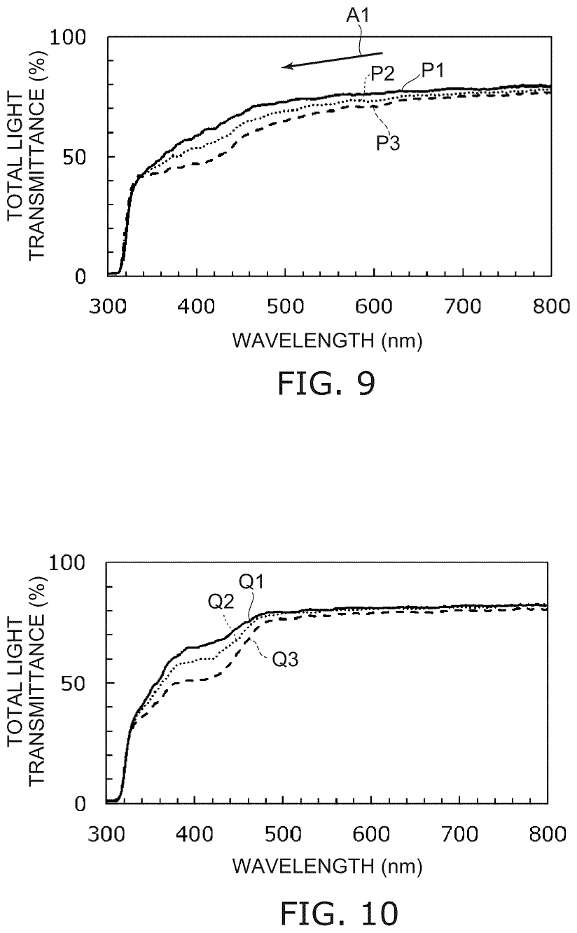

FIG. 9 is a graph showing the relationship between the wavelength and the total light transmittance measured in Examples.

FIG. 10 is a graph showing the relationship between the wavelength and the total light transmittance measured in Comparative Examples.

Furthermore, the wavelength conversion members 320 in Examples 3 to 5 and the wavelength conversion members C in Comparative Examples 2 to 4 were produced under the conditions shown in FIG. 8. To be specific, in Example 3, 2.080 g of an acrylic resin, 0.900 g of a thiol resin, 0.270 g of a scattering material silicone resin powder, 0.021 g of a photoinitiator, and 0.090 g of red InP-QDC were mixed to obtain a resin composition.

In Example 4, 2.079 g of an acrylic resin, 0.900 g of a thiol resin, 0.272 g of a scattering material silicone resin powder, 0.021 g of a photoinitiator, and 0.150 g of red InP-QDC were mixed to obtain a resin composition.

In Example 5, 2.079 g of an acrylic resin, 0.904 g of a thiol resin, 0.270 g of a scattering material silicone resin powder, 0.021 g of a photoinitiator, and 0.270 g of red InP-QDC were mixed to obtain a resin composition.

In Comparative Example 2, 2.970 g of an acrylic resin, 0.270 g of a scattering material silicone resin powder, 0.030 g of a photoinitiator, and 0.120 g of a complex that absorbs at least one of blue light and green light and emits red light (a red complex/as an example, a β-diketone europium-metal complex) were mixed to obtain a resin composition.

In Comparative Example 3, 2.969 g of an acrylic resin, 0.272 g of a scattering material silicone resin powder, 0.030 g of a photoinitiator, and 0.210 g of a red complex were mixed to obtain a resin composition.

In Comparative Example 4, 2.970 g of an acrylic resin, 0.270 g of a scattering material silicone resin powder, 0.030 g of a photoinitiator, and 0.330 g of a red complex were mixed to obtain a resin composition.

Each of these resin compositions was formed into a sheet shape, and the wavelength conversion members 320 of Examples and the wavelength conversion members C of Comparative Examples were obtained by the method described above. The thickness of the resin layer (sheet) not including the barrier film was 81 μm for Example 3, 83 μm for Example 4, 82 μm for Example 5, 76 μm for Comparative Example 2, 80 μm for Comparative Example 3, and 81 μm for Comparative Example 4.

The total light transmittances of the wavelength conversion members 320 of Examples 3 to 5 and the wavelength conversion members C of Comparative Examples 2 to 4 were measured when the wavelengths of the incident light were changed from 300 nm to 800 nm. The measurement results are shown in FIGS. 8 to 10. In FIG. 9, P1, P2, and P3 correspond to the results of measuring the total light transmittances of the wavelength conversion members 320 of Example 3, Example 4, and Example 5, respectively. In FIG. 10, Q1, Q2, and Q3 correspond to the results of measuring the total light transmittances of the wavelength conversion members C of Comparative Example 2, Comparative Example 3, and Comparative Example 4, respectively.

As shown in FIG. 8, when the total light transmittance for the green light having a wavelength of 546 nm is defined as a second light transmittance T2 and the total light transmittance for the red light having a wavelength of 700 nm is defined as a third light transmittance T3, T2/T3 was 0.95 for Example 3, 0.94 for Example 4, 0.92 for Example 5, 0.98 for Comparative Example 2, 0.98 for Comparative Example 3, and 0.97 for Comparative Example 4. As described above, for Examples, T2/T3≤0.96 is satisfied between the second light transmittance T2 and the third light transmittance T3 of the wavelength conversion member 320. On the other hand, for Comparative Examples 2 to 4 containing the red complex, which does not absorb green light, T2/T3≥0.97.

In addition, as shown in FIG. 9, for Examples 3 to 5, the second light transmittance T2 for the green light having a wavelength from 500 nm to 600 nm of the incident light tended to decrease as the wavelength of the green light becomes short, as indicated by the arrow A1. In contrast, as shown in FIG. 10, for Comparative Examples, even when the wavelength of the green light becomes short from 600 nm to 500 nm, the second light transmittance T2 tended to be substantially constant. This is because the red complex does not absorb green light.

### 1.4. Summary

As described above, the light-emitting module 300 according to the present embodiment includes the light-emitting device 100 including the first light-emitting element 121 that outputs the first light having a peak wavelength included in a range from 430 nm to 480 nm, and the second light-emitting element 122 that outputs the second light having a peak wavelength included in a range from 500 nm to 600 nm, and the wavelength conversion member 320 that absorbs light having a wavelength included in at least one of the first light and the second light and outputs the third light having a peak wavelength included in a range from 600 nm to 780 nm. The first light-emitting element 121 and the second light-emitting element 122 are disposed in the light-emitting device 100, and the wavelength conversion member 320 is disposed separately from the light-emitting device. With such a structure, the wavelength conversion member 320 can be disposed at a position away from the first light-emitting element 121 and the second light-emitting element 122, and the light density of the first light or the second light that excites the wavelength conversion member 320 is reduced, so that the reliability of the light-emitting module 300 can be improved.

The wavelength conversion member 320 is disposed in a planar shape along the light-emitting direction of the light-emitting device 100. With such a configuration, the light-emitting device 100 can be mounted as a backlight of the light-emitting module 300.

The wavelength conversion member 320 includes quantum dots. With such a configuration, the wavelength conversion member 320 that can achieve the technical idea of the present disclosure can be specifically produced.

When the second light transmittance, which is the total light transmittance for the second light of the wavelength conversion member 320, is denoted by T2, and the third light transmittance, which is the total light transmittance for the third light of the wavelength conversion member, is denoted by T3, T2/T3≤0.96. The second light transmittance T2 of the wavelength conversion member 320 decreases as the wavelength of the second light becomes short. With such a configuration, the optical properties of the wavelength conversion member 320 suitable for achieving the technical idea of the present disclosure are specifically determined.

### 2. Other Embodiments

Although the embodiment of the present disclosure has been described above, the present disclosure is not limited to the above. For example, in the above embodiment, the first light-emitting element 121 and the second light-emitting element 122 are disposed in the light-emitting device 100 and the wavelength conversion member 320 is disposed separately from the light-emitting device 100, but the present disclosure is not limited to this aspect.

Specifically, for example, the light-emitting device 100 may include only one light-emitting element that outputs the first light. The light-emitting element and a first wavelength conversion member that absorbs light having a wavelength included in the first light and outputs the second light may be disposed in the light-emitting device 100, and a second wavelength conversion member that absorbs light having a wavelength included in at least one of the first light and the second light and outputs the third light may be disposed outside the light-emitting device 100. Even with such a configuration, a highly reliable light-emitting module using a phosphor can be obtained as in the above embodiment.

Embodiments according to the present disclosure have been described above with reference to specific examples. However, the present invention is not limited to these specific examples. All aspects that can be practiced by a person skilled in the art modifying the design as appropriate based on the above-described embodiments of the present disclosure are also included in the scope of the present invention, as long as they encompass the spirit of the present invention. In addition, in the scope of the concepts of the present invention, a person skilled in the art can conceive of various modifications and alterations, and those modifications and alterations also fall within the scope of the present invention.

What is claimed is:

1. A light-emitting module comprising:
a light-emitting device comprising:
a first light-emitting element configured to output first light having a peak wavelength in a range from 430 nm to 480 nm; and
a second light-emitting element configured to output second light having a peak wavelength in a range from 500 nm to 600 nm; and
a wavelength conversion member configured to absorb light having a wavelength comprised in at least one of the first light and the second light, and output third light having a peak wavelength in a range from 600 nm to 780 nm, wherein
the wavelength conversion member is disposed separately from the light-emitting device.

2. The light-emitting module according to claim 1, wherein
the wavelength conversion member is disposed in a planar shape along a light-emitting direction of the light-emitting device.

3. The light-emitting module according to claim 1, wherein
the wavelength conversion member comprises a quantum dot.

4. The light-emitting module according to claim 3, wherein
the quantum dot comprised in the wavelength conversion member contains red InP.

5. The light-emitting module according to claim 1, wherein
T2/T3≤0.96, where T2 is a second light transmittance being a total light transmittance for the second light of the wavelength conversion member, and T3 is a third light transmittance being a total light transmittance for the third light of the wavelength conversion member.

6. The light-emitting module according to claim 5, wherein
the second light transmittance decreases as a wavelength of the second light becomes short.

7. A light-emitting module comprising:
a light-emitting device comprising:
a light-emitting element configured to output first light having a peak wavelength in a range from 430 nm to 480 nm; and
a first wavelength conversion member configured to absorb light having a wavelength comprised in the first light and output second light having a peak wavelength in a range from 500 nm to 600 nm; and
a second wavelength conversion member configured to absorb light having a wavelength comprised in at least one of the first light and the second light, and output third light having a peak wavelength in a range from 600 nm to 780 nm, wherein
the light-emitting element and the first wavelength conversion member are disposed in the light-emitting device, and
the second wavelength conversion member is disposed separately from the light-emitting device.
